(19) United States
(12) Patent Application Publication
(10) Pub. No.: US 2014/0318167 A1
(43) Pub. Date: Oct. 30, 2014

(54) EVAPORATOR, COOLING DEVICE, AND ELECTRONIC APPARATUS

(71) Applicant: FUJITSU LIMITED, Kawasaki-shi (JP)

(72) Inventor: Hiroki Uchida, Isehara (JP)

(73) Assignee: FUJITSU LIMITED, Kawasaki-shi (JP)

(21) Appl. No.: 14/244,121

(22) Filed: Apr. 3, 2014

(30) Foreign Application Priority Data
Apr. 26, 2013 (JP) 2013-093405

(51) Int. Cl. H05K 7/20

(52) U.S. Cl. CPC H05K 7/20309; H05K 7/20318
USPC 62/259.2; 62/519; 62/513

(57) ABSTRACT

An evaporator includes: a porous medium that has a plurality of tubular projections; a vapor chamber and a liquid chamber that are separated by the porous medium, the liquid chamber also serving as a liquid reservoir; a case that has a first portion that is connected with a vapor line, a second portion that is connected with a liquid line at one side, and a plurality of protrusions that are provided on the first portion; and a high thermal conductivity member that is provided inside the liquid chamber, the high thermal conductivity member extending from the one side that is connected with the liquid line to an opposite side located opposite to the one side, the high thermal conductivity member having a higher thermal conductivity than the second portion.

### CROSS-REFERENCE TO RELATED APPLICATION

This application is based upon and claims the benefit of priority of the prior Japanese Patent Application No. 2013-093405, filed on Apr. 26, 2013, the entire contents of which are incorporated herein by reference.

### FIELD

The embodiment discussed herein is related to an evaporator, a cooling device, and an electronic apparatus.

### BACKGROUND

For example, as a type of cooling device that cools a heat-generating element such as an electronic component provided in an electronic apparatus such as a computer, cooling devices using a two-phase vapor-liquid flow exist. Such cooling devices achieve high cooling performance by utilizing the latent heat of vaporization that is generated when a working fluid in liquid phase evaporates and changes to gaseous phase.

For example, a loop heat pipe (LHP) exists as such a cooling device. A loop heat pipe includes an evaporator having a porous medium (wick), and a condenser. In the loop heat pipe, the outlet of the evaporator and the inlet of the condenser are connected by a vapor line, and the outlet of the condenser and the inlet of the evaporator are connected by a liquid line, with a working fluid sealed inside the loop heat pipe.

Such a loop heat pipe is able to transport heat by, for example, circulating the working fluid by the capillary force of the porous medium without using a liquid transport pump or the like.

In some loop heat pipes, for example, the liquid line is provided with a liquid transport pump for cases where the pressure loss of the circulation path is large, such as when a heat-receiving section and a heat-dissipating section are separated by a large distance and the heat transport distance is large, or when the heat-receiving section is made thinner to provide a narrower channel as in the case of a micro-channel.

If a flat porous medium is used for an evaporator provided in the loop heat pipe as mentioned above, sufficient cooling performance may not be obtained owing to its small evaporation area.

There are also loop heat pipes in which, in order to provide a larger evaporation area for improved cooling performance, the porous medium and the heating surface are provided with irregularities, and are fitted into each other. However, in a case where the amount of evaporation increases with an increase in the amount of heat generated by the heat-generating element, the working fluid is not readily supplied to the end portion on the heating surface side of the porous medium, and dry-out occurs. Consequently, the evaporation area becomes smaller, leading to a sharp reduction in cooling performance.

Further, it is conceivable to provide the evaporator with a liquid chamber that also serves as a liquid reservoir, and connect a liquid line to one side of the liquid chamber. In this case, if the evaporator is enlarged in the direction of its plane to provide a larger evaporation area in order to cope with increases in the amount of heat generated by the heat-generating element, the temperature of the working fluid in liquid phase inside the liquid chamber tends to become higher at the side opposite to the one side connected with the liquid line. Consequently, vapors (air bubbles) tend to form, causing a sharp decrease in cooling performance.

The followings are reference documents.
[Document 1] Japanese Laid-open Patent Publication No. 11-95873
[Document 2] Japanese Laid-open Patent Publication No. 2007-247931
[Document 3] Japanese Laid-open Patent Publication No. 2009-115396
[Document 4] Japanese Laid-open Patent Publication No. 09-186278
[Document 5] Japanese Laid-open Patent Publication No. 06-29683
[Document 6] Japanese National Publication of International Patent Application No. 2010-527432

### SUMMARY

According to an aspect of the invention, an evaporator includes: a porous medium that has a plurality of tubular projections; a vapor chamber and a liquid chamber that are separated by the porous medium, the liquid chamber also serving as a liquid reservoir; a case that has a first portion that is connected with a vapor line, the first portion defining the vapor chamber, a second portion that is connected with a liquid line at one side, the second portion having a lower thermal conductivity than the first portion, the second portion defining the liquid chamber, and a plurality of protrusions that are provided on the first portion, the plurality of protrusions protruding toward the second portion, the plurality of protrusions being each fitted into each of the plurality of tubular projections of the porous medium; and a high thermal conductivity member that is provided inside the liquid chamber, the high thermal conductivity member extending from the one side that is connected with the liquid line to an opposite side located opposite to the one side, the high thermal conductivity member having a higher thermal conductivity than the second portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic cross-sectional view illustrating a configuration of an evaporator provided in a cooling device according to this embodiment;

FIG. 2 is a schematic perspective view illustrating the cooling device and a configuration of an electronic apparatus including the cooling device according to this embodiment;

FIG. 3 is an exploded perspective view illustrating a configuration of the evaporator provided in the cooling device according to this embodiment;

FIG. 4 is an exploded perspective view illustrating a configuration of a modification of the evaporator provided in the cooling device according to this embodiment;

FIG. 5 is an exploded perspective view illustrating a configuration of a modification of the evaporator provided in the cooling device according to this embodiment;

FIG. 6 is an exploded perspective view illustrating a configuration of a modification of the evaporator provided in the cooling device according to this embodiment;

FIG. 7 is an exploded perspective view illustrating a configuration of a modification of the evaporator provided in the cooling device according to this embodiment;

FIG. 8 is a schematic cross-sectional view illustrating a configuration of an evaporator which is considered at the time of conception of the embodiment;

FIG. 9A illustrates the distribution of liquid temperature inside a liquid chamber when an evaporator according to a comparative example which is not provided with a high thermal conductivity member is used, in a case where a heat-generating element generates about 170 W of heat;

FIG. 9B illustrates the distribution of liquid temperature in a liquid chamber when the evaporator according to this embodiment which is provided with a high thermal conductivity member is used, in a case where a heat-generating element generates about 170 W of heat;

FIG. 10 is a schematic cross-sectional view illustrating a configuration of an evaporator whose porous medium is provided with nine tubular projections;

FIG. 11 is a schematic cross-sectional view illustrating a configuration of the evaporator according to the comparative example which is not provided with a high thermal conductivity member; and

FIG. 12 illustrates the advantageous effects of the cooling device according to this embodiment.

### DESCRIPTION OF EMBODIMENT

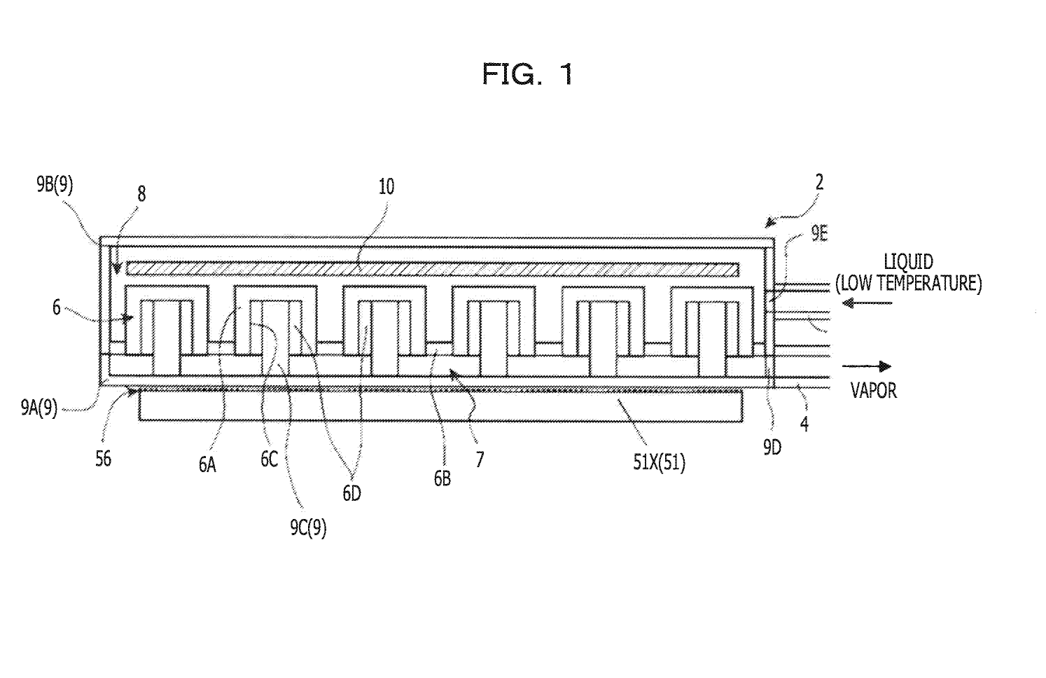

Hereinafter, an evaporator, a cooling device, and an electronic apparatus according to the embodiment will be described with reference to FIGS. 1 to 12.

The cooling device according to this embodiment is, for example, a cooling device that cools a heat-generating element such as an electronic component provided in an electronic apparatus such as a computer (for example, a server or a personal computer). The electronic apparatus is also referred to as electronic equipment. Further, the electronic component is, for example, a CPU or an LSI chip.

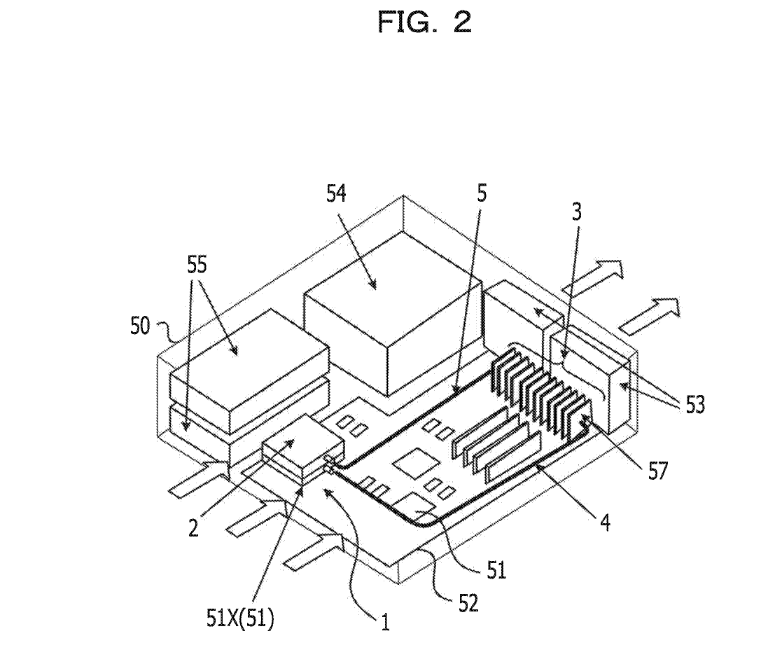

First, for example, as illustrated as FIG. 2, the electronic apparatus according to this embodiment includes, inside a housing 50, a wiring board 52 (for example, a printed circuit board) on which a plurality of electronic components 51 are mounted, an air blower fan 53 that cools the electronic components 51 on the wiring board 52 with air, a power supply 54, and a hard disk drive (HDD) 55 that is an auxiliary storage device.

The plurality of electronic components 51 include an electronic component that is a heat-generating element, that is, a heat-generating component. In this example, the heat-generating component is a central processing unit (CPU) 51X. Because the CPU 51X as a heat-generating component is not sufficiently cooled with the air from the air blower fan 53 alone, a cooling device 1 (which is a loop heat pipe in this case) is mounted in order to cool the CPU 51X.

In this embodiment, the cooling device 1 is a cooling device using a two-phase vapor-liquid flow, which achieves high cooling performance by utilizing the latent heat of vaporization generated when a working fluid in liquid phase evaporates and changes to gaseous phase.

That is, the cooling device 1 according to this embodiment is a loop heat pipe with a working fluid (for example, ethanol) sealed inside the loop heat pipe. The cooling device 1 includes an evaporator 2 that causes a working fluid in liquid phase to evaporate, a condenser 3 that causes a working fluid in gaseous phase to condense, a vapor line 4 that connects the evaporator 2 and the condenser 3 and through which the working fluid in gaseous phase flows, and a liquid line 5 that connects the condenser 3 and the evaporator 2 and through which the working fluid in liquid phase flows.

As illustrated as FIG. 1, in the loop heat pipe 1, the evaporator 2 is provided with a porous medium 6. The working fluid may be circuited by the capillary force of the porous medium 6 to thereby transport heat.

That is, in this example, the evaporator 2 is thermally connected to the CPU 51X that is a heat-generating component. For example, the evaporator 2 is brought into intimate contact with the CPU 51X provided on the wiring board 52 via thermal grease 56 so that the heat from the CPU 51X propagates to the evaporator 2.

As a result, a part of the working fluid in liquid phase supplied to the evaporator 2 seeps from the surface of the porous medium 6 provided in the evaporator 2. The working fluid in liquid phase that has seeped from the surface of the porous medium 6 evaporates (vaporizes) with the heat that has propagated from the CPU 51X that is a heat-generating component, and changes to gaseous phase.

As illustrated as FIG. 2, the working fluid in gaseous phase flows into the condenser 3 via the vapor line 4. As a result, the heat absorbed in the evaporator 2 is transported to the condenser 3.

Then, the working fluid in gaseous phase that has entered the condenser 3 condenses (liquefies) as the working fluid is cooled in the condenser 3, and changes to liquid phase. As a result, the heat transported to the condenser 3 is dissipated. In this example, the condenser 3 is provided near the air blower fan 53, and the condenser 3 is provided with a radiator fin 57. Then, the heat transported to the condenser 3 is dissipated via the radiator fin 57, and is released to the outside of the housing 50 with the air from the air blower fan 53.

Another radiating member such as a radiator plate may be provided instead of the radiator fin 57. Alternatively, a radiating member may not be provided, and cooling may be done by directly blowing air to the pipe. While cooling is done by an air cooling-type cooling unit in this example, cooling may be done by a water cooling-type cooling unit. This working fluid in liquid phase flows into the evaporator 2 via the liquid line 5.

In this way, the working fluid circulates through a circulation path formed by the evaporator 2, the vapor line 4, the condenser 3, and the liquid line 5.

In particular, the evaporator 2 is configured as described below in this embodiment.

In the following description, a thin flat evaporator suited for efficiently cooling a flat heat-generating element (the CPU 51X as a heat-generating component in this example) will be described as an example of the evaporator 2. A thin flat evaporator will be also referred to as thin evaporator or flat evaporator.

As illustrated as FIG. 1, the evaporator 2 according to this embodiment includes the porous medium (wick) 6, a vapor chamber 7 and a liquid chamber 8 separated by the porous medium 6, a case 9, and a high thermal conductivity member 10. FIG. 1 merely depicts that the high thermal conductivity member 10 is provided in the liquid chamber 8, and is not intended to limit, for example, the shape and arrangement of the high thermal conductivity member 10.

In this example, the porous medium 6 is a porous medium with a low thermal conductivity. Specifically, the porous medium 6 is a porous polytetrafluoroethylene (PTFE) resin-sintered body (porous medium made of resin).

In this embodiment, in particular, the porous medium 6 has a plurality of tubular projections 6A. That is, the porous medium 6 includes a flat portion 6B, and the plurality of tubular projections 6A provided on the flat portion 6B. The plurality of tubular projections 6A are provided so as to project to the liquid chamber 8 side (that is, toward an upper portion 9B of the case 9 described later) with respect to the flat portion 6B. Each of the tubular projections 6A has an insertion hole 6C on the vapor chamber 7 side (that is, on the side of a lower portion 9A of the case 9 described later). Each of a plurality of protrusions 9C provided on the lower portion 9A of the case 9 described later is inserted into the insertion hole 6C. The lateral side of the insertion hole 6C is provided with a plurality of grooves 6D extending in the depth direction of the insertion hole 6C.

The case 9 has the lower portion (first portion) 9A, and the upper portion (second portion) 9B. The lower portion 9A is connected with the vapor line 4, and defines the vapor chamber 7. The upper portion 9B is connected with the liquid line 5 at one side (the right side in FIG. 1), and defines the liquid chamber 8.

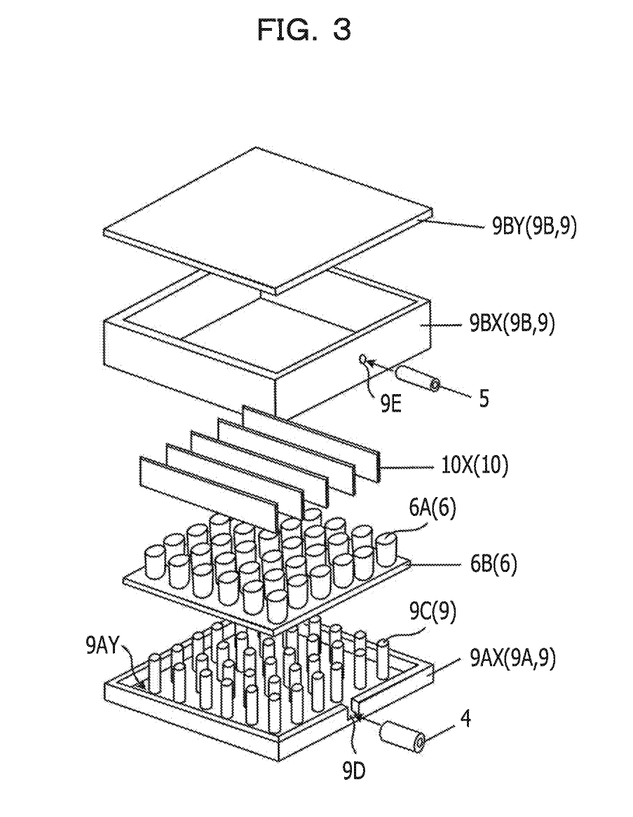

That is, a vapor line connection opening 9D (outlet of the evaporator 2) is provided at one side (the right side in FIG. 1) of the lower portion 9A of the case 9, and the vapor line 4 is connected to the vapor line connection opening 9D. In this way, the vapor line 4 is connected to one side of the vapor chamber 7 defined by the lower portion 9A of the case 9 constituting the evaporator 2. In this example, as illustrated as FIG. 3, the lower portion 9A of the case 9 is formed by a base plate 9AX including a recess 9AY. The vapor line 4 is connected to the vapor line connection opening 9D provided in the base plate 9AX.

Further, as illustrated as FIG. 1, a liquid line connection opening 9E (inlet of the evaporator 2) is provided at one side of the upper portion 9B of the case 9. The liquid line 5 is connected to the liquid line connection opening 9E. In this way, the liquid line 5 is connected to one side of the liquid chamber 8 defined by the upper portion 9B of the case 9 constituting the evaporator 2. In this example, as illustrated as FIG. 3, the upper portion 9B of the case 9 is formed by a frame 9BX, and a cover 9BY. The liquid line 5 is connected to the liquid line connection opening 9E provided in the frame 9BX.

While in this example the vapor line 4 and the liquid line 5 are connected to one side of the case 9 as illustrated as FIG. 1, this is not intended to be restrictive. For example, the liquid line 5 may be connected to one side of the case 9, and the vapor line 4 may be connected to the other side.

The lower portion 9A of the case 9 is thermally connected to the CPU 51X that is a heat-generating component. As a result, the vapor chamber 7 defined by the lower portion 9A of the case 9 is located close to the CPU 51X, and the liquid chamber 8 defined by the upper portion 9B of the case 9 is located far from the CPU 51X. Further, the upper portion 9B of the case 9 has a lower thermal conductivity than the lower portion 9A. For example, as will be described later, the thermal conductivity of the upper portion 9B of the case 9 may be made lower than that of the lower portion 9A by forming the upper portion 9B of the case 9 from stainless steel, and forming the lower portion 9A of the case 9 from copper. This minimizes propagation of the heat from the CPU 51X that is a heat-generating component to the working fluid in liquid phase, thereby minimizing increases in the temperature of the working fluid in liquid phase.

Further, the case 9 has the plurality of protrusions 9C provided on the lower portion 9A. The plurality of protrusions 9C extend toward the upper portion 9B, and are each fitted into the corresponding one of the plurality of projections 6A of the porous medium 6. That is, the lower portion 9A of the case 9 is provided with the plurality of protrusions 9C that protrude toward the upper portion 9B, and the plurality of protrusions 9C are each fitted into the insertion hole 6C provided in each of the plurality of tubular projections 6A of the porous medium 6. In this example, as illustrated as FIG. 3, the plurality of protrusions 9C are formed integrally on the surface of the recess 9AY of the base plate 9AX constituting the lower portion 9A of the case 9. As illustrated as FIG. 1, the plurality of protrusions 9C are each fitted into the insertion hole 6C provided in each of the plurality of tubular projections 6A of the porous medium 6, so that the center axis of the protrusions 9C coincides with the center axis of the tubular projections 6A of the porous medium 6 (that is, the center axis of the insertion hole 6C).

In this way, the porous medium 6 is accommodated in the case 9. In particular, the plurality of protrusions 9C are each fitted into the corresponding one of the plurality of tubular projections 6A of the porous medium 6 in such a way that a space is defined between the back of the porous medium 6 (the underside in FIG. 1) and the surface (the top side in FIG. 1) of the lower portion 9A of the case 9. As a result, the space defined between the back of the porous medium 6 and the surface of the lower portion 9A of the case 9 serves as the vapor chamber 7. In this example, the plurality of grooves 6D are formed on the lateral side of the insertion hole 6C provided in each of the plurality of tubular projections 6A of the porous medium 6, and the space defined between the grooves 6D, that is, the space between the bottom of the grooves 6D formed in the insertion hole 6C and the lateral side of each of the protrusions 9C also serves as a part of the vapor chamber 7. The space defined between the surface (the top side in FIG. 1) of the porous medium 6 and the surface (the underside in FIG. 1) of the upper portion 9B of the case 9 serves as the liquid chamber 8. The liquid chamber 8 also serves as a liquid reservoir that stores the working fluid in liquid phase.

Owing to a capillary phenomenon, the working fluid in liquid phase that enters the liquid chamber 8 and is stored in the liquid chamber 8 penetrates from the periphery of the plurality of tubular projections 6A of the porous medium 6 and seeps toward the vapor chamber 7. Meanwhile, when the CPU 51X as a heat-generating component generates heat, the heat propagates to the lower portion 9A of the case 9, and further, to each of the plurality of the protrusions 9C. Then, the heat that has propagated to each of the plurality pf protrusions 9C causes the working fluid in liquid phase that has seeped toward the vapor chamber 7 to evaporate (vaporize), and changes to gaseous phase. In particular, the porous medium 6 is provided with the plurality of tubular projections 6A to provide a larger evaporation area, thereby improving cooling performance. Further, by providing the lower portion 9A of the case 9 with the protrusions 9C, and fitting the protrusions 9C onto the tubular projections 6A, the penetration distance of the working fluid in liquid phase becomes uniform.

As a result, for example, even in cases where the amount of heat generated by the heat-generating element increases to cause an increase in the amount of evaporation, such as when the CPU 51X as a heat-generating component becomes larger and generates more heat to cause an increase in the amount of evaporation, situations where the working fluid in liquid phase is not readily supplied to the surface on the vapor chamber 7 side (that is, the end portion on the heating surface side) are avoided, thereby minimizing occurrence of dry-out, a decrease in evaporation area, and the resulting sharp drop in cooling performance. In this way, the porous medium 6 provided with the tubular projections 6A for increased evaporation area is made uniform in thickness, the wetting of the porous medium 6 in contact with the protrusions 9C is made uniform, and the working fluid in liquid phase is efficiently evaporated from the porous medium 6 having an increased evaporation area, thereby ensuring stable cooling performance.

In a case where the evaporator 2 is provided with the liquid chamber 8 that also serves as a liquid reservoir, and the liquid line 5 is connected to one side of the liquid chamber 8, when the evaporator 2 is enlarged in the direction of its plane to provide a lager evaporation area in order to deal with an increase in the amount of heat generated by the heat-generating element, the temperature of the working fluid in liquid phase inside the liquid chamber 8 tends to become higher at the side opposite to the one side connected with the liquid line 5. Consequently, vapors (air bubbles) tend to form, causing a sharp decrease in cooling performance.

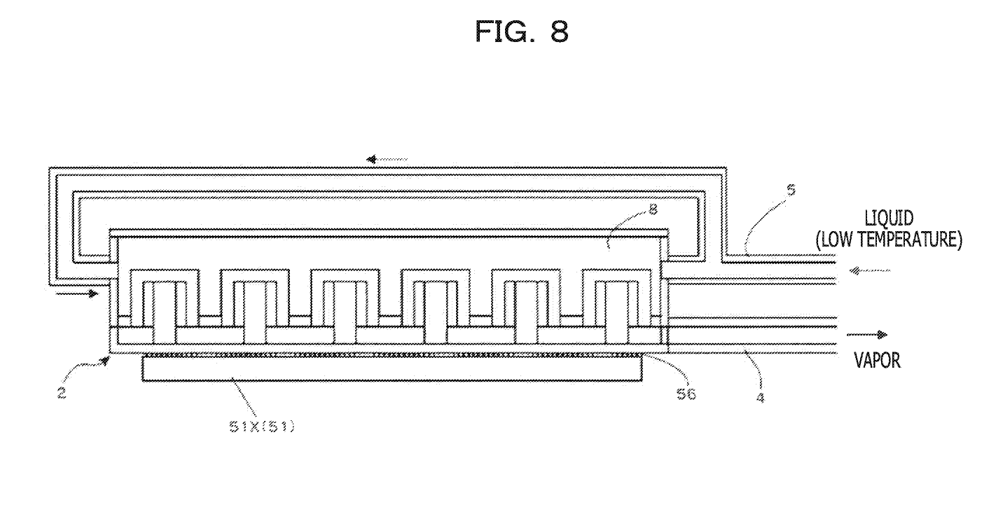

In this case, for example, as illustrated as FIG. 8, it is also conceivable to divide the liquid line 5 into two branches, one being connected to one side of the liquid chamber 8 and the other being connected to the opposite side of the liquid chamber 8. However, the provision of such additional piping leads to an increase in cost. Further, it is also difficult to secure the space for mounting such piping.

Accordingly, in this embodiment, as illustrated as FIG. 1, the high thermal conductivity member 10 is provided inside the liquid chamber 8. The high thermal conductivity member 10 extends from the one side connected with the liquid line 5 toward the side opposite to the one side, and has a higher thermal conductivity than the upper portion 9B of the case 9. Consequently, the difference in the temperature of the working fluid in liquid phase inside the liquid chamber 8 may be made smaller, thereby making it possible to keep the inside of the liquid chamber 8 in a substantially uniform, low temperature state. As a result, it is possible to keep the working fluid in liquid phase from evaporating inside the liquid chamber 8, or keep the pressure inside the liquid chamber 8 from rising, thereby enabling stable circulation of the working fluid, stable operation of the loop heat pipe, and high cooling performance.

The high thermal conductivity member 10 preferably has a thermal conductivity higher than, for example, about 100 W/mK. In this embodiment, because the upper portion 9B of the case 9 is made of stainless steel with a low thermal conductivity of about 20 to about 30 W/mK, the high thermal conductivity member 10 has a thermal conductivity higher than this value. A working fluid in liquid phase has low thermal conductivity. In the case of water, its thermal conductivity is about 0.6 W/mK, and in the case of ethanol or acetone, its thermal conductivity is about 0.2 W/mK. Consequently, the high thermal conductivity member 10 has a higher thermal conductivity than the working fluid in liquid phase. Further, the porous medium 6 has low thermal conductivity. For example, the thermal conductivity of PTFE is about 0.2 W/mK to about 0.3 W/mK. Consequently, the high thermal conductivity member 10 has a higher thermal conductivity than the porous medium.

In this embodiment, as illustrated as FIG. 3, the high thermal conductivity member 10 includes a plurality of plate-like members 10X. Each of the plate-like members 10X is a rectangular plate-like member. The plurality of plate-like members 10X are disposed in a vertical orientation between the plurality of tubular projections 6A on the flat portion 6B of the porous medium 6. As a result, the inside of the liquid chamber 8 may be kept in a substantially uniform, low temperature state not only in a case where the inside of the liquid chamber 8 is entirely filled with the working fluid in liquid phase but also on a case where the working fluid in liquid phase is present only at the lower side in the interior of the liquid chamber 8.

Each of the plate-like members 10X as the high thermal conductivity member 10 is a plate-like member made of a high thermal conductivity material. For example, a plate-like member made of a metal, a carbon fiber, diamond, an inorganic material, or the like with high thermal conductivity (good thermal conductivity) may be used. Examples of a metal with high thermal conductivity include copper (thermal conductivity: about 380 W/mK) and aluminum (in the case of a die cast, thermal conductivity: about 100 W/mK; in the case of a wrought product, thermal conductivity: about 200 W/mK). A carbon fiber with high thermal conductivity refers to a carbon fiber with high thermal conductivity with respect to the axial direction (for example, a pitch-based carbon fiber with a thermal conductivity of about 800 W/mK). In addition, diamond has a thermal conductivity of about 1000 W/mK to 2000 W/mK. Further, examples of an inorganic material with high thermal conductivity include ceramics such as aluminum nitride (AlN) (thermal conductivity: about 150 W/mK) and silicon carbonate (SIC) (thermal conductivity: about 200 W/mK).

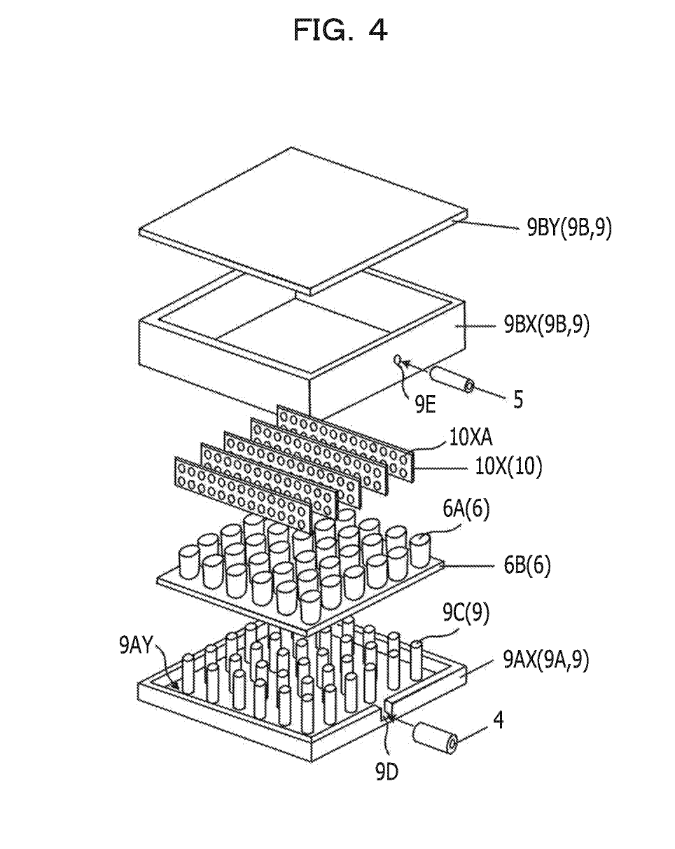

As illustrated as FIG. 4, preferably, the plurality of plate-like members 10X each have a plurality of holes 10XA that penetrate each of the plate-like members 10X in the thickness direction. As a result, the conductivity of heat from one side of the liquid chamber 8 to the opposite side may be improved, without hindering the flow of the working fluid in liquid phase inside the liquid chamber 8.

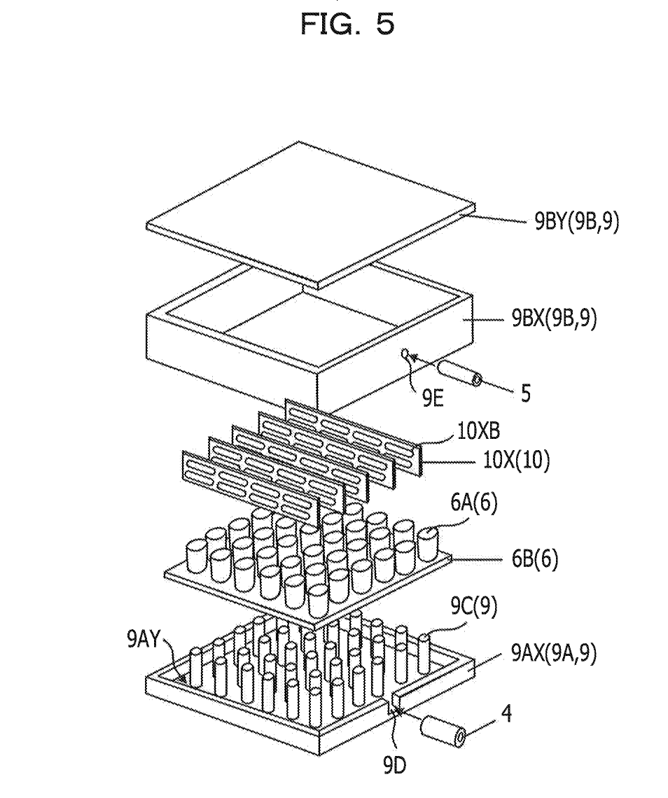

In particular, more preferably, as illustrated as FIG. 5, the plurality of holes are formed as elongated holes 10XB that extend from one side to the opposite side. That is, more preferably, the holes are the elongated holes 10XB that extend in the longitudinal direction of the plate-like members 10X, with a length that is larger in the longitudinal direction of the plate-like members 10X than in the lateral direction. As a result, the conductivity of heat from one side of the liquid chamber 8 to the opposite side may be further improved, while providing less hindrance to the flow of the working fluid in liquid phase inside the liquid chamber 8.

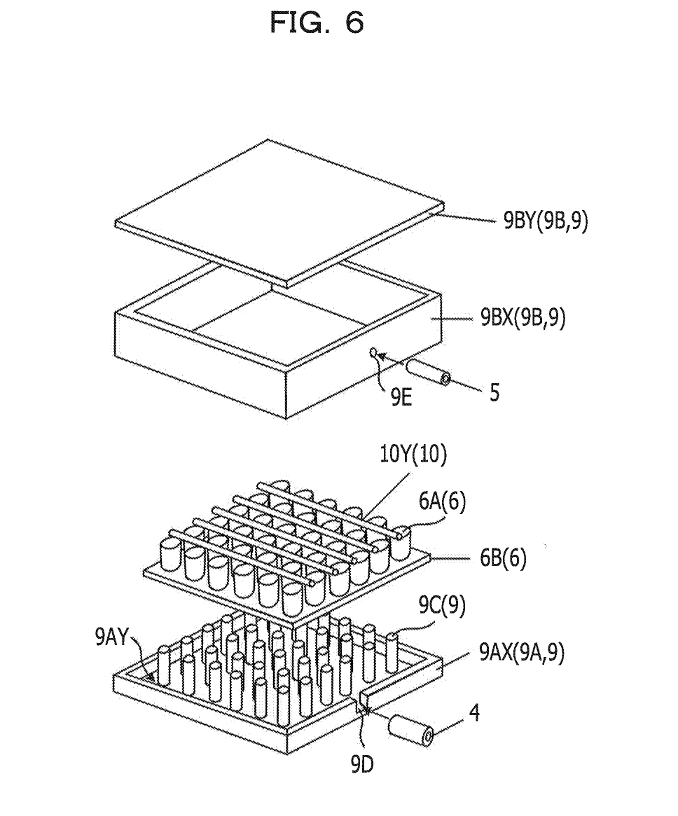

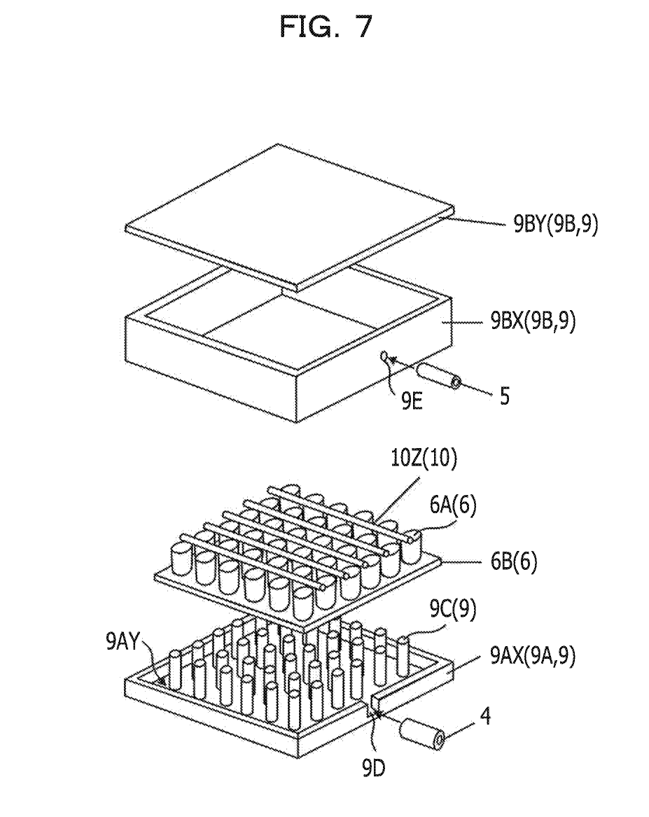

The high thermal conductivity member 10 is not limited to the above. For example, a plurality of plate-like members, a plurality of rod-like members, or a plurality of heat pipes may be provided as the high thermal conductivity member 10. Instead of providing the plurality of plate-like members 10X as the high thermal conductivity member 10 as in the above embodiment, for example, as illustrated as FIG. 6, a plurality of rod-like members 10Y may be provided. Alternatively, for example, as illustrated as FIG. 7, a plurality of heat pipes 10Z (with a thermal conductivity equivalent to about 1000 W/mK to 3000 W/mK) may be provided.

Hereinafter, a specific configuration example of a loop heat pipe as the cooling device 1 according to this embodiment will be described.

First, the evaporator 2 has outside dimensions of about 75 mm by about 75 mm, and has a height of about 25 mm. Because the lower portion 9A of the case 9 of the evaporator 2 is thermally connected to the heat-generating element 51X, the lower portion 9A is made of copper that has high thermal conductivity, and the upper portion 9B of the case 9 is made of stainless steel that has relatively low thermal conductivity. This minimizes propagation of the heat from the heat-generating element 51X to the working fluid in liquid phase via the lower portion 9A of the case 9. Further, in this example, non-porous PTFE is attached to the inner wall surface of the upper portion 9B of the case 9, that is, the wall surface of the liquid chamber 8 that directly contacts the working fluid in liquid phase, thereby blocking thermal leaks from the upper portion 9B of the case 9 to the working fluid in liquid phase.

To attach the porous medium 6, a total of 36 protrusions (circular cylinders; projections) 9C, six in the longitudinal direction and six in the transverse direction, are arranged in a grid on the bottom of the lower portion 9A of the case 9 (see FIG. 3). Each of the protrusions 9C has a diameter (outside diameter)φ of about 5 mm, and a height of about 15 mm.

The porous medium 6 is a porous PTFE resin-sintered body (porous medium made of resin) with a porosity of about 40% and an average pore diameter of about 20 μm. The porous medium 6 mentioned above is provided with a total of 36 tubular projections (cylindrical projections) 6A, six in the longitudinal direction and six in the transverse direction, so as to be arranged in a grid. Each of the tubular projections 6A has an outside diameter φ of about 9 mm, and an inside diameter φ of about 7 mm. The center axis of the tubular projections (cylindrical projections) 6A, that is, the center axis of the insertion hole 6C provided on the back side of each of the tubular projections (cylindrical projections) 6A coincides with the center axis of the protrusions 9C provided on the lower portion 9A of the case 9. Each of the protrusions 9C provided on the bottom of the lower portion 9A of the case 9 is inserted into the insertion hole 6C provided on the back side of each of the tubular projections (cylindrical projections) 6A, thereby attaching the porous medium 6 to the lower portion 9B of the case 9 (see FIG. 1).

In this example, the insertion hole 6C provided on the back side of each of the tubular projections (cylindrical projections) 6A has a depth of about 13 mm. Consequently, when the porous medium 6 is attached to the lower portion 9A of the case 9 by inserting each of the protrusions 9C provided on the bottom of the lower portion 9A of the case 9 into the insertion hole 6C provided on the back side of each of the tubular projections (cylindrical projections) 6A, a space of about 2 mm is defined between the bottom of the case 9 (that is, the bottom of the lower portion 9A of the case 9) and the back of the porous medium 6 (that is, the back of the flat portion 6B of the porous medium 6), and this space serves as the vapor chamber 7 (see FIG. 1).

The diameter of the insertion hole 6C provided on the back side of each of the tubular projections (cylindrical projections) 6A is set smaller than the outside diameter of the protrusions 9C of the case 9 by about 50 μm to about 200 μm. This ensures sufficiently close contact when the porous medium 6 is attached to the lower portion 9A of the case 9.

Further, the grooves 6D are uniformly provided on the lateral side (inner wall) of the insertion hole 6C (see FIG. 1). The grooves 6D have a width of about 1 mm and a depth of about 1 mm, and extend in the depth direction (vertical direction) of the insertion hole 6C. As a result, the space defined between the grooves 6D, that is, the space between the bottom of each of the grooves 6D formed on the lateral side of the insertion hole 6C and the lateral side of each of the protrusions 9C of the case 9 also serves as a part of the vapor chamber 7.

By coupling the upper portion 9B of the case 9 to the lower portion 9A of the case 9 attached with the porous medium 6, an internal space with a height of about 5 mm is defined between the porous medium 6, that is, the top of the tubular projections (cylindrical projections) 6A of the porous medium 6 and the underside of the upper portion 9B of the case 9 in a state in which the porous medium 6 is accommodated in the case 9. This internal space, and the space between the plurality of tubular projections 6A of the porous medium 6 serve as the liquid chamber 8 that also serves as a liquid reservoir (see FIG. 1).

The vapor chamber 7 of the evaporator 2 prepared in this way (that is, the lower portion 9A of the case 9 which defines the vapor chamber 7 of the evaporator 2), and the inlet of the condenser 3 are connected by the vapor line 4 (see FIG. 2). Further, one side of the liquid chamber 8 of the evaporator 2 (that is, one side of the upper portion 9B of the case 9 which defines the liquid chamber 8 of the evaporator 2), and the outlet of the condenser 3 are connected by the liquid line 5 (see FIG. 2).

In this example, the vapor line 4 is a copper pipe with an outside diameter of about 6 mm and an inside diameter of 5 mm. The vapor line 4 has a length of about 300 mm. The liquid line 5 is a copper pipe with an outside diameter of about 4 mm and an inside diameter of 3 mm. The liquid line 5 has a length of about 200 mm. The condenser 3 has dimensions of about 150 nm in weight, about 50 mm in height, and about 45 mm in length. In this example, an aluminum plate fin (radiator fin 57) is attached by caulking to a condensing pipe provided in the condenser 3 (see FIG. 2). As this condensing pipe, a grooved pipe made of copper with an outside diameter of about 6.35 mm is used. The radiator fin 57 made of aluminum has a thickness of about 0.2 mm and a pitch of about 1.5 mm.

Ethanol is used as the working fluid. After evacuating the loop heat pipe 1 into a vacuum, the loop heat pipe 1 is filled with a suitable amount of saturated ethanol.

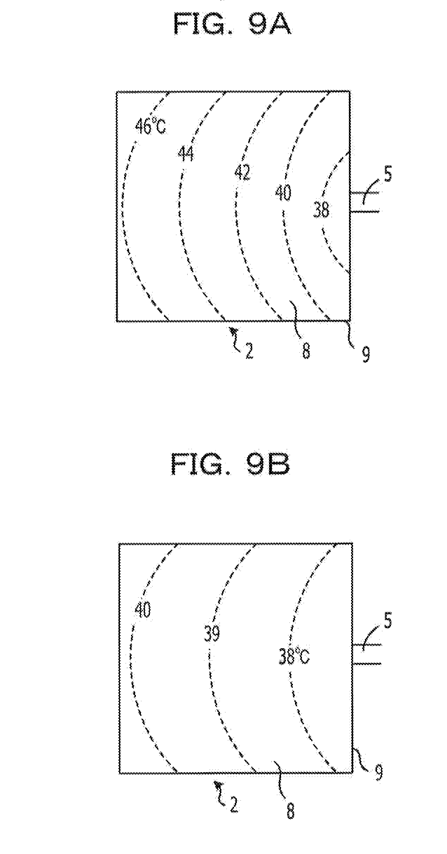

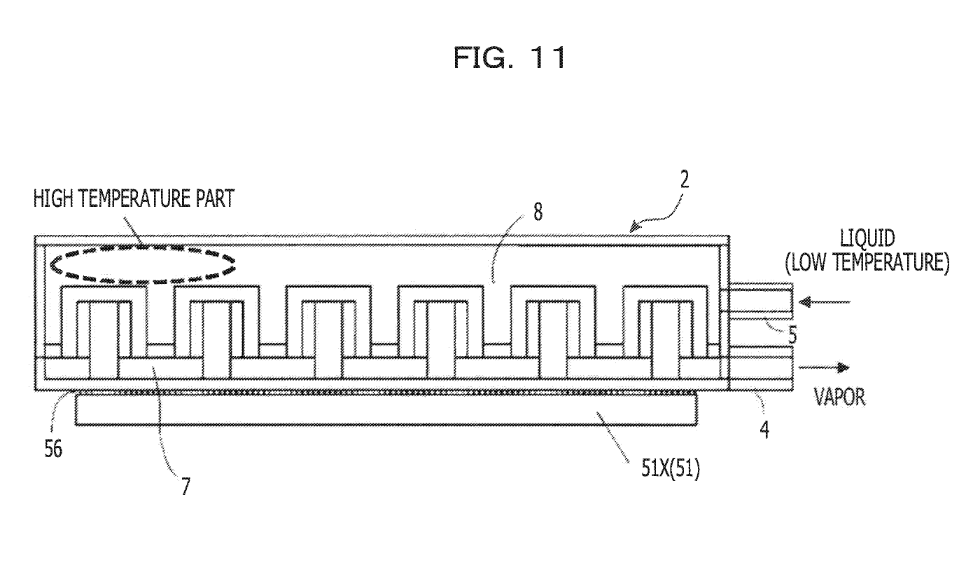

As illustrated as FIG. 11, for the evaporator 2 provided in the loop heat pipe 1, that is, the evaporator 2 prepared without provision of the high thermal conductivity member 10, the temperature of the working fluid in liquid phase (liquid temperature) inside the liquid chamber 8 of the evaporator 2 is measured. It is found as a result that the liquid temperature becomes higher from one side of the liquid chamber 8 which is connected with the liquid line 5 toward the opposite side, with decreasing proximity from the end face of the case 9 of the evaporator 2 which is connected with the liquid chamber 8 (see FIG. 9A).

Consequently, the isotherm of liquid temperature is regarded as being substantially parallel to the end face of the case 9 of the evaporator 2 to which the liquid line 5 is connected, and as the high thermal conductivity member 10, the plurality of plate-like members (copper plates; plate members made of copper) 10X are placed in the liquid chamber 8 that also serves as a liquid reservoir, along a direction perpendicular to the isotherm of liquid temperature, that is, along a direction perpendicular to the end face of the case 9 of the evaporator 2 to which the liquid line 5 is connected (see FIG. 5).

That is, in the space between the plurality of tubular projections 6A of the porous medium 6 inside the liquid chamber 8 that also serves as a liquid reservoir, the plurality of plate-like members (copper plates) 10X extending from one side of the liquid chamber 8 which is connected with the liquid line 5 to the side opposite to the one side are disposed in a vertical orientation so that the plurality of plate-like members (copper plates) 10X are arranged in a direction orthogonal to the direction that points from the one side to the other side (see FIG. 5).

In this example, five plate-like members (copper plates) 10X with a width of about 10 mm, a length of about 60 mm, and a thickness of about 0.5 mm are each placed so as to be interposed in the gap (about 1 mm) between the plurality of tubular projections (cylindrical projections) 6A of the porous medium 6. While the upper portion 9B of the case 9 is made of stainless steel, the high thermal conductivity member 10 is made of copper. Therefore, the high thermal conductivity member 10 has a higher thermal conductivity than the upper portion 9B of the case 9. Further, in this example, each of the plate-like members (copper plates) 10X is provided with the plurality of elongated holes (punched slits) 10XB that are elongated along its longitudinal direction. As a result, higher thermal conductivity may be attained for the longitudinal direction of the plate-like members (copper plates) 10X, while providing less hindrance to the flow of the working fluid in liquid phase inside the liquid chamber 8.

For example, the temperature distribution of the working fluid in liquid phase inside the liquid chamber 8 at about 170 W of heat generation is considered. At this time, in the case of the comparative example in which the high thermal conductivity member 10 is not provided inside the liquid chamber 8 (see FIG. 11), as illustrated as FIG. 9A, a temperature difference of about 8° C. develops, and a high temperature part (see FIG. 11) develops for the liquid temperature inside the liquid chamber 8. To the contrary, in a case where the high thermal conductivity member 10 is provided inside the liquid chamber 8 as in the specific configuration example according to this embodiment (see FIGS. 1 and 5), as illustrated as FIG. 9B, it is confirmed that the temperature difference is smaller at about 2° C., and the inside of the liquid chamber 8 may be maintained in a substantially uniform, low temperature state, thereby making it possible to supply a low-temperature liquid-phase working fluid to the porous medium 6.

In particular, by providing the high thermal conductivity member 10 inside the liquid chamber 8 as in the specific configuration example according to this embodiment (see FIGS. 1 and 5), the temperature of the high temperature part that develops inside the liquid chamber 8 may be lowered from about 45° C. to about 40° C.

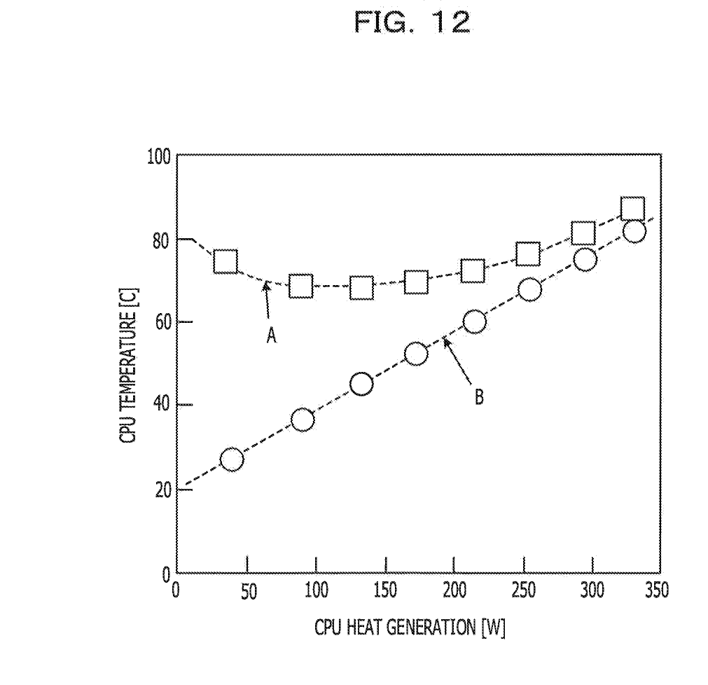

At this time, as for the surface temperature of the CPU 51X at about 170 W of heat generation, the surface temperature is about 70° C. in the case of the comparative example in which the high thermal conductivity member 10 is not provided inside the liquid chamber 8 (see FIG. 11), whereas the surface temperature is about 50° C. (see FIG. 12) in the case of the specific configuration example according to this embodiment (see FIGS. 1 and 5).

As for the surface temperature (maximum surface temperature) of the CPU 51X at the maximum heat generation of 330 W, the surface temperature is about 85° C. in the case of the comparative example in which the high thermal conductivity member 10 is not provided inside the liquid chamber 8 (see FIG. 11), whereas the surface temperature is about 80° C. (see FIG. 12) in the case of the specific configuration example according to this embodiment (see FIGS. 1 and 5).

In this regard, at about 170 W of heat generation, good cooling performance is attained in the case of the specific configuration example according to this embodiment (see FIGS. 1 and 5). In this case, the temperature difference between the surface temperature of the CPU 51X, and the temperature of the high temperature part that develops inside the liquid chamber 8 is about 10° C. Also, at the maximum heat generation of 330 W, good cooling performance is attained in the case of the specific configuration example according to this embodiment (see FIGS. 1 and 5), and it is assumed that the temperature difference is similar to the above-mentioned value.

Then, it follows that the temperature of the high temperature part that develops inside the liquid chamber 8 at the maximum heat generation of 330 W is about 75° C. in the case of the comparative example in which the high thermal conductivity member 10 is not provided inside the liquid chamber 8 (see FIG. 11), whereas the temperature of the high temperature part is about 70° C. in the case of the specific configuration example according to this embodiment (see FIGS. 1 and 5). In this example, ethanol is used as the working fluid in liquid phase, and its boiling point is 78.37° C. Consequently, in the case of the comparative example in which the high thermal conductivity member 10 is not provided inside the liquid chamber 8 (see FIG. 11), the temperature of the high temperature part that develops inside the liquid chamber 8 is close to the boiling point, which may cause vapors to form and reduce cooling performance.

To the contrary, in the case of the specific configuration example according to this embodiment (see FIGS. 1 and 5), the provision of the high thermal conductivity member 10 inside the liquid chamber 8 as mentioned above makes it possible to keep the inside of the liquid chamber 8 at a substantially uniform temperature, and lower the temperature of the high temperature part that develops inside the liquid chamber 8 to move the temperature away from the boiling point. This may minimize formation of vapors and the resulting decrease in cooling performance. As a result, stable cooling performance may be attained, without dry-out of the porous medium 6 inside the evaporator 2 which causes the CPU 51X with a large size to reach a serious state involving abnormally high temperature.

While the plate-like members (copper plates) 10X are provided with the elongated holes 10XB in this example, the plate-like members (copper plates) 10X may be simply provided with holes (see FIG. 4), or may not be provided with holes (see FIG. 3). While the plate-like members (copper plates) 10X are used as the highly terminally conductive member 10 in this example, the same effect may be obtained by, for example, using a metal such as aluminum, a carbon fiber, or an inorganic material such as ceramics as the highly terminally conductive member 10, forming the highly terminally conductive member 10 in a rod-like shape (see FIG. 6), or using heat pipes (see FIG. 7). For example, in the case of forming the highly terminally conductive member 10 in a rod-like shape, the same effect may be obtained by placing a plurality of copper rods with a diameter of about 2.5 mm. In the case of using heat pipes, the same effect may be obtained by placing a plurality of micro heat pipes with a thickness of about 4 to about 5 mm and a length of about 60 mm in which water is sealed.

Therefore, the evaporator, the cooling device, and the electronic apparatus according to this embodiment offer the advantage of being able to minimize a decrease in cooling performance and provide stable cooling performance even in cases where the amount of heat generated by the heat-generating element increases.

In particular, by use of the cooling device including a thin flat evaporator as in the above-mentioned embodiment, a flat heat-generating element that generates a large amount of heat such as an electronic component or a print circuit board (wiring board) may be cooled efficiently. As a result, it is possible to improve the performance of an electronic apparatus such as a computer, thereby increasing its reliability.

Incidentally, the amount of heat generated by heat-generating components in electronic apparatuses typically represented by computer servers is increasing year by year. In particular, the amount of heat generated by CPUs, which are high heat-generating components mounted in computer servers, is increasingly sharply as CPUs improve in computing speed and become increasingly multi-core.

Accordingly, there are marked increases in the component size of CPUs. For example, while the typical sizes of CPUs range from about 30 mm to about 40 mm in length and breadth in the past, recently, CPUs are becoming larger with sizes ranging from about 60 mm to about 80 mm in length and breadth. For this reason, flat evaporators for cooling devices used to cool such large CPUs also have to cope with increases in the amount of heat generation and increases in size.

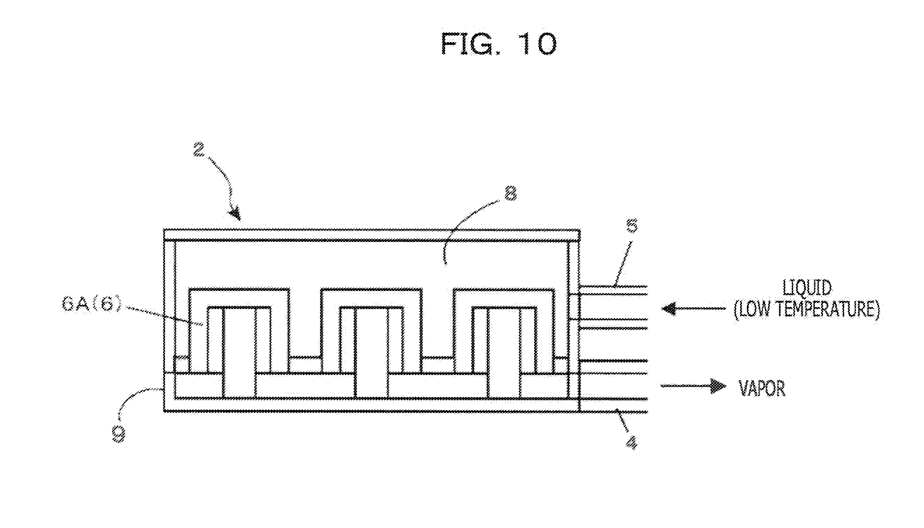

In this regard, in a case where the porous medium 6 having the plurality of tubular projections 6A as in the above-mentioned embodiment is used, the amount of heat that may be handled is determined by the evaporation area per one tubular projection. Consequently, if the number of tubular projections 6A is small, it is not possible to cope with increases in the amount of heat generated by the heat-generating component, causing dry-out. For example, as illustrated as FIG. 10, when it is attempted to cool the CPU 51X with a large size mentioned above (maximum heat generation in operation: about 330 W) by using an evaporator in which the number of tubular projections 6A is reduced and a total of three tubular projections, three in the longitudinal direction and three in the transverse direction, are arranged in a grid, dry-out occurs.

In this case, the dry-out depends on the speed at which the working fluid in liquid phase seeps from the porous medium 6. Accordingly, by increasing the evaporation area (contact area), that is, the number of tubular projections 6A in accordance with the amount of heat generated by the heat-generating component, it is possible to cope with increases in the amount of heat generation.

Accordingly, in the specific configuration example mentioned above (see FIGS. 1 and 5), the number of tubular projections 6A is increased to a total of 36, that is, the evaporator 2 with a large size (large area) is used so that the evaporator 2 may be adapted to cool the above-mentioned large CPU 51X that generates a large amount of heat.

For example, while the evaporator 2 is increased in size by provision of a total of 36 tubular projections 6A, it is confirmed that by using the evaporator 2 according to the comparative example in which the high thermal conductivity member 10 is not provided inside the liquid chamber 8 (see FIG. 11), as indicated by a broken line A in FIG. 12, the surface temperature of the CPU 51X with a large size may be lowered to the vicinity of about 85° C. even in a state in which the CPU 51X with a large size generates the maximum amount of heat of about 330 W. In this way, it is possible to keep the CPU 51X with a large size from reaching a serious state involving abnormally high temperature.

However, when the number of tubular projections 6A is increased to make the evaporator 2 larger as in the specific configuration example mentioned above, a temperature difference develops in the working fluid in liquid phase inside the liquid chamber 8, creating a high temperature part and a low temperature part. That is, in a case where the evaporator 2 has a small size (for example, in a case where the number of tubular projections 6A is nine in total; see FIG. 10), a cooled working fluid in liquid phase is supplied from the liquid line 5 into the liquid chamber 8. Therefore, the working fluid in liquid phase inside the liquid chamber 8 is kept in a substantially uniform, low temperature state.

As opposed to the above, in a case where the evaporator 2 increases in size, and the liquid chamber 8 is enlarged in the direction of its plane (see FIG. 11), although the side in the interior of the liquid chamber 8 which is connected with the liquid line 5 is relatively low in temperature owing to continuous supply of the working fluid in liquid phase via the liquid chamber 8, the working fluid in liquid phase at a side in the interior of the liquid chamber 8 located opposite to the side connected with the liquid line 5 becomes high temperature owing to heat leaks (heating) from the vapor chamber 7 located below the liquid chamber 8. As a result, vapors (air bubbles) tend to form in the high temperature part inside the liquid chamber 8, causing, for example, dry-out, which may cause a decrease in cooling performance.

Accordingly, by providing the high thermal conductivity member 10 inside the liquid chamber 8 as in the specific configuration example mentioned above, the difference in the temperature of the working fluid in liquid phase inside the liquid chamber 8 is made smaller so that a high temperature part does not develop. Therefore, cooling performance does not decrease, and stable cooling performance may be attained.

The above-mentioned cooling device 1 described as the specific configuration example (see FIGS. 1 and 5) is actually used to cool the CPU (maximum heat generation in operation: about 330 W) 51X with a large size of about 60 mm×60 mm, which is a large heat-generating component inside the electronic apparatus that is actually running, and then the surface temperature of the CPU 51X with a large size is measured. As a result, it is confirmed that, as illustrated as FIG. 12, even in a state in which the CPU 51X with a large size is running at high speed and generating the maximum heat of about 330 W, the surface temperature of the CPU 51X with a large size is about 80° C., indicating that the CPU 51X with a large size may be cooled in a satisfactory manner.

It is also confirmed that in a case where the above-mentioned evaporator 2 described as the specific configuration example (see FIGS. 1 and 5) is used, as indicated by broken lines A and B in FIG. 12, as compared with the evaporator 2 according to the comparative example in which the high thermal conductivity member 10 is not provided inside the liquid chamber 8 (see FIG. 11), the surface temperature of the CPU 51X may be made lower across the entire range of heat generation of the CPU 51X.

In this way, regardless of the amount of heat generated by the CPU 51X, including when the CPU 51X with a large size is running at full capacity, that is, when the CPU 51X is generating the maximum amount of heat of about 330 W, stable cooling performance is attained, without dry-out of the porous medium 6 inside the evaporator 2 which causes the CPU 51X with a large size to reach a serious state involving abnormally high temperature.

For example, as indicated by the broken lines A and B in FIG. 12, in a high heat generation range where the amount of heat generated by the CPU 51X with a large size ranges from about 200 W to 330 W, the flow rate of the working fluid in liquid phase is large (the flow is fast). Therefore, as compared with the case of using the evaporator 2 according to the comparative example in which the high thermal conductivity member 10 is not provided inside the liquid chamber 8 (see FIG. 11), the effect of this embodiment in lowering the surface temperature of the CPU 51X is not so great. However, the effect is nevertheless great in the sense that by lowering the temperature of the high temperature part that develops inside the liquid chamber 8, a decrease in cooling performance due to formation of vapors may be minimized.

In medium to low heat generation ranges where the amount of heat generated by the CPU 51X with a large size is not more than about 200 W, the flow rate of the working fluid in liquid phase decreases. Consequently, in the case of using the evaporator 2 according to the comparative example in which the high thermal conductivity member 10 is not provided inside the liquid chamber 8 (see FIG. 11), as indicated by the broken line A in FIG. 12, the liquid temperature tends to rise in regions inside the liquid chamber 8 which are located far from the liquid line 5. As a result, sufficient cooling performance is not attained, and operation of the loop heat pipe 1 becomes unstable.

As opposed to this, by using the evaporator 2 according to the specific configuration mentioned above (see FIGS. 1 and 5), as indicated by the broken line B in FIG. 12, sufficient cooling performance is attained in the medium to low heat generation ranges of not more than 200 W, thereby making it possible to stabilize the operation of the loop heat pipe 1. In this way, even in a case where the size of the evaporator 2 increases, and the liquid chamber 8 is enlarged in the direction of its plane, it is possible to cool the CPU (heat-generating component) 51X across the entire heat generation range from low heat generation to high heat generation.

As described above, it is confirmed that with the cooling device 1 according to the specific configuration example mentioned above, a decrease in cooling performance may be minimized, and stable cooling performance may be attained, even in a case where the amount of heat generated by the heat-generating element increases.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An evaporator comprising:
a porous medium that has a plurality of tubular projections;
a vapor chamber and a liquid chamber that are separated by the porous medium, the liquid chamber also serving as a liquid reservoir;
a case that has
a first portion that is connected with a vapor line, the first portion defining the vapor chamber,
a second portion that is connected with a liquid line at one side, the second portion having a lower thermal conductivity than the first portion, the second portion defining the liquid chamber, and
a plurality of protrusions that are provided on the first portion, the plurality of protrusions protruding toward the second portion, the plurality of protrusions being each fitted into each of the plurality of tubular projections of the porous medium; and
a high thermal conductivity member that is provided inside the liquid chamber, the high thermal conductivity member extending from the one side that is connected with the liquid line to an opposite side located opposite to the one side, the high thermal conductivity member having a higher thermal conductivity than the second portion.

2. The evaporator according to claim 1, wherein the high thermal conductivity member includes a plurality of plate-like members, a plurality of rod-like members, or a plurality of heat pipes.

3. The evaporator according to claim 1, wherein:
the high thermal conductivity member includes a plurality of plate-like members; and
the plurality of plate-like members are disposed in a vertical orientation between the plurality of tubular projections.

4. The evaporator according to claim 3, wherein each of the plurality of plate-like members has a plurality of holes, the plurality of holes penetrating each of the plurality of plate-like members in a thickness direction.

5. The evaporator according to claim 4, wherein each of the plurality of holes is an elongated hole that extends from the one side toward the opposite side.

6. A cooling device comprising:
an evaporator to evaporate a working fluid in liquid phase;
a condenser to condense a working fluid in gaseous phase;
a vapor line to flow the working fluid in gaseous phase through, the vapor line connecting the evaporator and the condenser; and
a liquid line to flow the working fluid in liquid phase through, the liquid line connecting the condenser and the evaporator,
wherein the evaporator includes
a porous medium that has a plurality of tubular projections,
a vapor chamber and a liquid chamber that are separated by the porous medium, the liquid chamber also serving as a liquid reservoir,
a case that has
a first portion that is connected with a vapor line, the first portion defining the vapor chamber,
a second portion that is connected with a liquid line at one side, the second portion having a lower thermal conductivity than the first portion, the second portion defining the liquid chamber, and
a plurality of protrusions that are provided on the first portion, the plurality of protrusions protruding toward the second portion, the plurality of protrusions being each fitted into each of the plurality of tubular projections of the porous medium, and
a high thermal conductivity member that is provided inside the liquid chamber, the high thermal conductivity member extending from the one side that is connected with the liquid line to an opposite side located opposite to the one side, the high thermal conductivity member having a higher thermal conductivity than the second portion.

7. The cooling device according to claim 6, wherein the high thermal conductivity member includes a plurality of plate-like members, a plurality of rod-like members, or a plurality of heat pipes.

8. The cooling device according to claim 6, wherein:
the high thermal conductivity member includes a plurality of plate-like members; and
the plurality of plate-like members are disposed in a vertical orientation between the plurality of tubular projections.

9. The cooling device according to claim 8, wherein each of the plurality of plate-like members has a plurality of holes, the plurality of holes penetrating each of the plurality of plate-like members in a thickness direction.

10. The cooling device according to claim 9, wherein each of the plurality of holes is an elongated hole that extends from the one side toward the opposite side.

11. An electronic apparatus comprising:
an electronic component that is provided on a wiring board; and
a cooling device to cool the electronic component,
wherein the cooling device includes
an evaporator to evaporate a working fluid in liquid phase,
a condenser to condense a working fluid in gaseous phase,
a vapor line to flow the working fluid in gaseous phase through, the vapor line connecting the evaporator and the condenser, and
a liquid line to flow the working fluid in liquid phase through, the liquid line connecting the condenser and the evaporator,
wherein the evaporator includes
a porous medium that has a plurality of tubular projections,
a vapor chamber and a liquid chamber that are separated by the porous medium, the liquid chamber also serving as a liquid reservoir,
a case that has
a first portion that is connected with a vapor line, the first portion defining the vapor chamber,
a second portion that is connected with a liquid line at one side, the second portion having a lower thermal conductivity than the first portion, the second portion defining the liquid chamber, and
a plurality of protrusions that are provided on the first portion, the plurality of protrusions protruding toward the second portion, the plurality of protrusions being each fitted into each of the plurality of tubular projections of the porous medium, and
a high thermal conductivity member that is provided inside the liquid chamber, the high thermal conductivity member extending from the one side that is connected with the liquid line to an opposite side located opposite to the one side, the high thermal conductivity member having a higher thermal conductivity than the second portion.

12. The electronic apparatus according to claim 11, wherein the high thermal conductivity member includes a plurality of plate-like members, a plurality of rod-like members, or a plurality of heat pipes.

13. The electronic apparatus according to claim 11, wherein:
the high thermal conductivity member includes a plurality of plate-like members; and
the plurality of plate-like members are disposed in a vertical orientation between the plurality of tubular projections.

14. The electronic apparatus according to claim 13, wherein each of the plurality of plate-like members has a plurality of holes, the plurality of holes penetrating each of the plurality of plate-like members in a thickness direction.

15. The electronic apparatus according to claim 14, wherein each of the plurality of holes is an elongated hole that extends from the one side toward the opposite side.
